(19) United States
(12) Patent Application Publication
(10) Pub. No.: US 2017/0027089 A1
(43) Pub. Date: Jan. 26, 2017

(54) MULTI-FUNCTIONAL SHEET FOR SHIELDING ELECTROMAGNETIC WAVES AND DISSIPATING HEAT AT HIGH PERFORMANCE

(71) Applicants: Jong Geun BAE, Daegu (KR); RNU Co., Ltd, Daegu (KR)

(72) Inventor: Jong Geun BAE, Daegu (KR)

(21) Appl. No.: 15/214,588

(22) Filed: Jul. 20, 2016

(30) Foreign Application Priority Data
Jul. 20, 2015 (KR) 10-2015-0102352
May 30, 2016 (KR) 10-2016-0066580

(51) Int. Cl. H05K 9/00; H05K 7/20

(52) U.S. Cl. CPC H05K 9/0088; H05K 7/20509

(57) ABSTRACT

Provided is a multi-functional sheet having both a function of surface-reflecting and absorbing electromagnetic waves and a function of dissipating heat. In a multi-functional sheet for shielding electromagnetic waves and dissipating heat at a high performance which is manufactured by pressing a metal layer to a graphite sheet, the metal layer is a metal sheet having a plurality of pores, the graphite sheet penetrates into the pores through pressing of rollers, a thickness of the metal sheet is made to be smaller through pressing of the rollers and sizes of the pores becomes smaller such that the metal sheet is coupled to the graphite sheet, and a depth by which the graphite penetrates into the pores through the pressing of the rollers is larger than 15% of the thickness of the metal sheet.

### CROSS-REFERENCE TO RELATED APPLICATION

This application claims priority from and the benefit under 35 U.S.C. §119(a) of Korean Patent Application No. 10-2015-0102352, filed on Jul. 20, 2015, and 10-2016-0066580, filed on May 30, 2016, which is hereby incorporated by reference for all purposes as if fully set forth herein.

### BACKGROUND OF THE INVENTION

1. Field of the Invention

The present invention relates to a multi-functional sheet having a function of shielding electromagnetic waves and dissipating heat at a high performance, and more particularly to a multi-functional sheet having both a function of surface-reflecting and absorbing electromagnetic waves and a function of dissipating heat.

2. Description of the Prior Art

In recent years, as the electronic devices have become slimmer, light-weighted, and smaller, the electric circuits embedded in the electronic devices has become highly functional, highly dense, highly integrated, and complex, causing the electromagnetic waves to generate noise and disorders.

The electromagnetic waves generate noise due to mutual disturbance of electric waves between the electronic devices, lower the efficiency of the electronic products, and shorten the life spans of the electronic devices.

Further, because the electromagnetic waves may do harm to the human bodies, a multi-functional sheet that may shield electromagnetic waves generated by the electronic devices and effectively emit dissipate heat generated by the electronic devices is required.

An electromagnetic wave shielding sheet according to the related art has a limit in increasing electromagnetic wave shielding performance because a sheet that uses a surface reflection of electromagnetic waves and a sheet that uses absorption of electromagnetic waves are applied separately. Further, because the electromagnetic wave shielding sheet functions simply to shield electromagnetic waves, an additional heat dissipating sheet should be used to dissipate heat so that it is difficult to implement a thin film and slimness of the product and the price of the product increases.

### SUMMARY OF THE INVENTION

The present invention has been made in an effort to solve the above-mentioned problems, and provides a multi-functional sheet that can implement a function of maximize an electronic wave shielding performance and efficiently dissipating heat.

In accordance with an aspect of the present invention, there is provided a multi-functional sheet for shielding electromagnetic waves and dissipating heat at a high performance which is manufactured by pressing a metal layer to a graphite sheet, wherein the metal layer is a metal sheet having a plurality of pores, the graphite sheet penetrates into the pores through pressing of rollers, a thickness of the metal sheet is made to be smaller through pressing of the rollers and sizes of the pores becomes smaller such that the metal sheet is coupled to the graphite sheet, and a depth by which the graphite penetrates into the pores through the pressing of the rollers is larger than 15% of the thickness of the metal sheet.

The multi-functional sheet may further include a release paper that is bonded to one surface of the metal sheet, and the graphite sheet is formed on an opposite surface of the metal sheet, and the release paper, the metal sheet, and the graphite sheet that are sequentially stacked are pressed by rollers.

The graphite sheet may include a first graphite sheet formed on one surface of the metal sheet and a second graphite sheet formed on an opposite surface of the metal sheet, and the first graphite sheet and the second graphite sheet penetrate into the pores to contact each other through pressing.

The metal sheet may include a first metal sheet formed on one surface of the graphite sheet and a second metal sheet formed on an opposite surface of the graphite sheet, and the graphite sheet penetrates into pores formed in the first metal sheet and pores formed in the second metal sheet.

According to another aspect of the present invention, there is provided a multi-functional sheet for shielding electromagnetic waves and dissipating heat at a high performance which is manufactured by pressing a metal layer to a graphite sheet, wherein the metal layer is formed on one surface or opposite surfaces of the graphite sheet through sputtering deposition and the stack structure of the metal layer and the graphite sheet is pressed to have a thickness of not more than 40 μm.

The present invention provides a multi-functional sheet having a high-performance electromagnetic wave shielding function that allows surface reflection of electromagnetic waves and internal absorption of electromagnetic waves and a high-performance heat dissipating function, and because an electronic device can be easily slimmed and made a thin film and can be mass-produced as an integral multi-functional sheet that implements an electromagnetic wave shielding function and a heat dissipating function, the multi-functional sheet has an excellent price competitiveness.

### BRIEF DESCRIPTION OF THE DRAWINGS

The above and other objects, features, and advantages of the present invention will be more apparent from the following detailed description taken in conjunction with the accompanying drawings, in which:

FIG. 1 is an exemplary view of a metal sheet according to a first embodiment of the present invention;

FIG. 2 illustrates data obtained by measuring shield of electronic waves of a multi-functional sheet according to a first embodiment of the present invention;

FIG. 3 illustrates data obtained by measuring heat dissipation of a multi-functional sheet according to a first embodiment of the present invention;

FIG. 4 is a sectional view of a metal sheet according to a first embodiment of the present invention;

FIG. 5 is a view for explaining a method for coupling a metal sheet and a graphite sheet according to a first embodiment of the present invention;

FIG. 6 is a view schematically illustrating a sectional structure of a multi-functional sheet according to the first embodiment of the present invention;

FIGS. 7 and 8 are views schematically illustrating a sectional structure of another multi-functional sheet according to the first embodiment of the present invention;

FIG. 9 is a view schematically illustrating a multi-functional sheet according to a second embodiment of the present invention;

FIG. 10 is a view schematically illustrating a multi-functional sheet having a protective layer according to a second embodiment of the present invention;

FIG. 11 illustrates data obtained by measuring shield of electronic waves of a multi-functional sheet according to a second embodiment of the present invention;

FIG. 12 illustrates data obtained by measuring shield of electronic waves of a multi-functional sheet according to a second embodiment of the present invention; and

FIG. 13 illustrates data obtained by measuring heat dissipation of a multi-functional sheet according to a second embodiment of the present invention.

### DETAILED DESCRIPTION OF THE EXEMPLARY EMBODIMENTS

The present invention provides a multi-functional sheet having an excellent shielding effect against electromagnetic waves and an excellent heat dissipating effect. Hereinafter, exemplary embodiments of the present invention will be described in detail with reference to the accompanying drawings.

### First Embodiment

A multi-functional sheet for shielding electromagnetic waves and dissipating heat at a high performance according to a first embodiment of the present invention is manufactured by pressing a metal layer on a graphite sheet, and in the first embodiment, the metal layer is a metal sheet 10a having a plurality of pores 11.

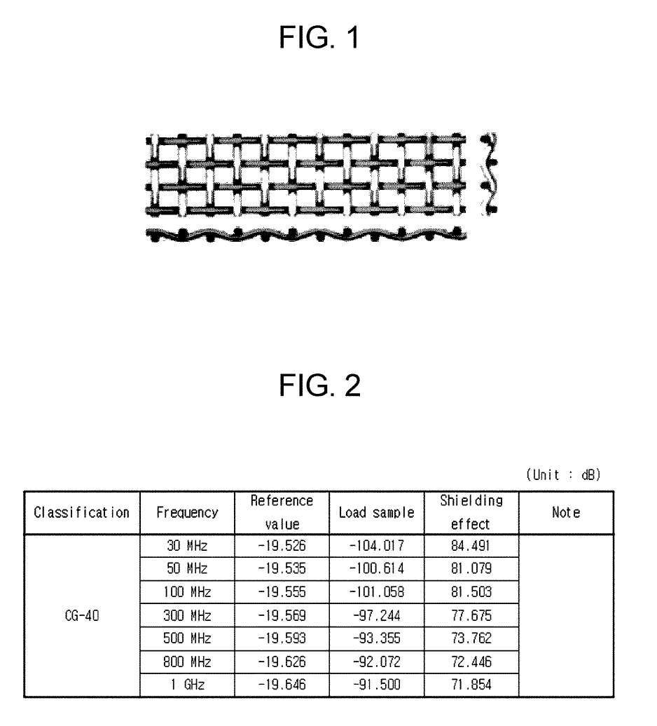

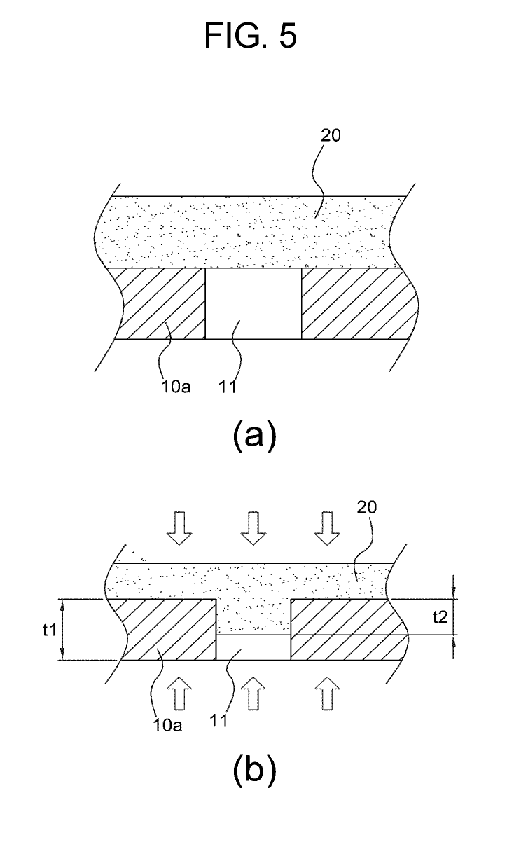

The metal sheet 10a may be a wire cloth or other metal woven nets having various structures that are obtained by weaving a metal wire that may absorb electromagnetic waves, by using a metal (copper, aluminum, zinc, silver, iron, or chrome) that surface-reflects electromagnetic waves and is conductive or a metal alloy thereof. The metal sheet 10a has about 100 meshes or more and a thickness of not more than 200 μm, and the thickness of the metal sheet 10a becomes about 70 μm by compressing the metal sheet 10a by a press or a roller. As illustrated in FIG. 4, the metal sheet 10a is compressed to have dense pores 11, and line contacts of the wire are converted to surface contacts, which increases a surface area in contact, so that a heat dissipating effect of the metal sheet 10a is improved while the metal sheet 10a has a function of shielding and absorbing electromagnetic waves. FIG. 1 is an exemplary view of a metal sheet according to a first embodiment of the present invention.

The graphite sheet 20 has an excellent heat dissipating function, and rolled and pressed together with the metal sheet 10a that is a high performance electronic wave shielding sheet to be coupled to the metal sheet 10a. Further, the metal sheet 10a and the graphite sheet 20 may be pressed by using a press. In the process of pressing the metal sheet 10a and the graphite sheet 20, the graphite sheet 20 having an excellent heat dissipating performance is located on the metal sheet 10a and is pressed together with the metal sheet 10a. Then, the graphite sheet 20 that is penetrated into the pores 11 while the sizes of the pores 11 of the metal sheet 10a decreases is coupled such that the metal sheet 10a and the graphite sheet 20 form an integral sheet. Accordingly, the multi-functional sheet of the present invention has a function of shielding electromagnetic waves and dissipating heat at a high performance. Further, the multi-functional sheet of the present invention has a heat dissipating effect because it is made to be an integral sheet without any thermal resistance by a bonding resin by coupling the metal sheet 10a and the graphite sheet 20 without using any adhesive.

Meanwhile, a product in which different sheets are combined by using an existing heat dissipating paint and an adhesive shows a low heat dissipating effect as compared with the heat dissipating characteristics of a single sheet because a thermal resistance is generated by a bonding resin used to bond the two sheets.

The following is an example of a multi-functional sheet for shielding electromagnetic waves and dissipating heat at a high performance, which has various structures, according to the first embodiment of the present invention.

Structure 1

The graphite sheet 20 is located on the metal sheet 10a. The thickness of the stack structure of the metal sheet 10a and the graphite sheet 20 is about 80 to 200 μm, and is made to about 40 to 120 μm after the stack structure passes between rollers.

Then, the rotational speed of the roller is 0.015 to 0.08 m/s. If the speed of the rollers is lower than 0.015 m/s, the productivity and efficiency of the multi-functional sheet deteriorates, and if the speed of the rollers is higher than 0.08 m/s, the sheet may be distorted or deformed so that the quality of the multi-functional sheet may deteriorate.

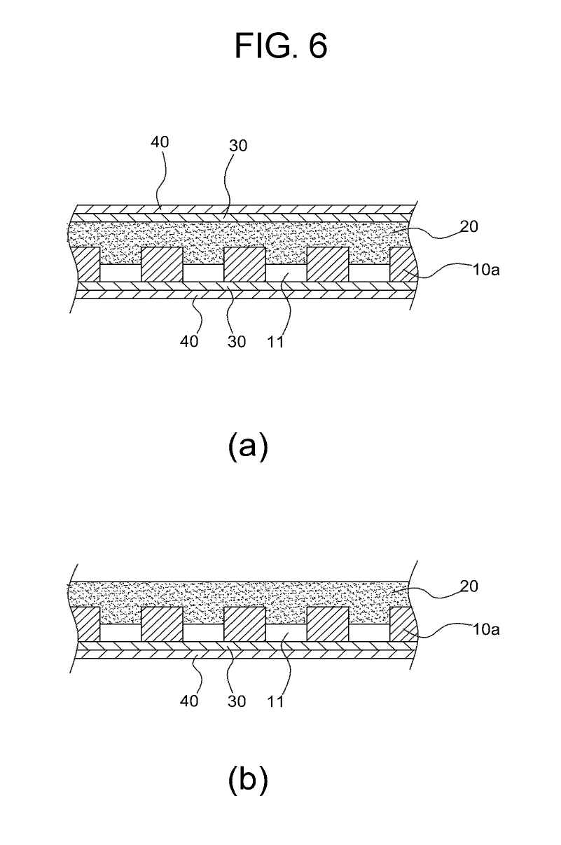

Meanwhile, as illustrated in FIG. 5, when the metal sheet 10a and the graphite sheet 20 pass between the rollers, a portion of the graphite sheet 20 penetrates into the pores by a pressure and the metal sheet 10a is made to be thinner by the pressure so that the sizes of the pores 11 become smaller. In this way, because the sizes of the pores 11 become smaller as the graphite sheet 20 penetrates into the pores 11, the metal sheets 10a and the graphite sheet 20 may be coupled to each other by pressing the two sheets without using a separate bonding resin.

When the graphite sheet 20 penetrates into the pores 11 by the pressure of the rollers, the penetration depth t2 of the graphite sheet 20 is larger than 15% of the thickness t1 of the metal sheet 10a in a state in which the metal sheet 10a and the graphite sheet 20 is pressed. Because the metal sheet 10a and the graphite sheet 20 are not stably coupled to each other so that they may be separated from each other or cannot show their performances properly when the penetration depth of the graphite sheet 20 is smaller than 15% of the thickness of the metal sheet 10a, the graphite sheet 20 should penetrate by not less than 15% of the thickness of the metal sheet 10a.

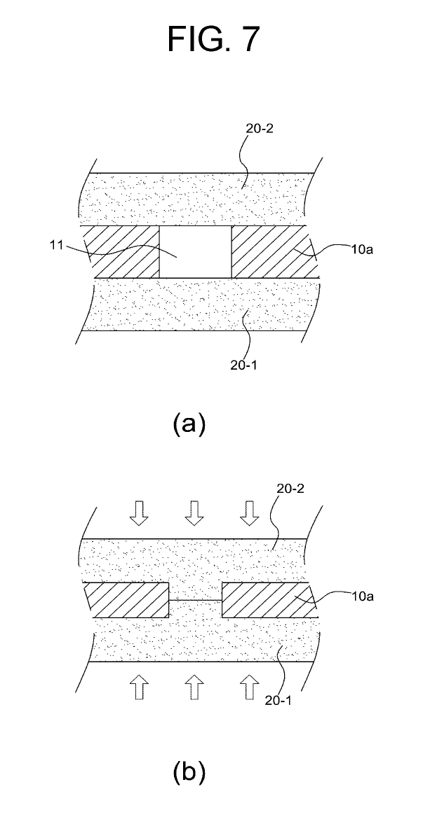

In this way, as illustrated in FIG. 6, after the metal sheet 10a and the graphite sheet 20 are pressed to be coupled to each other, a release paper (PET) 40 having an adhesive 30 with conductive or insulating characteristics on one or opposite surfaces of the multi-functional sheet.

Further, the release paper 40 may be attached to the metal sheet 10a before the metal sheet 10a and the graphite sheet 20 are pressed.

The shield rate of the multi-functional sheet is measured in a frequency area of 30 MHz to 1 GHz by the measurement standard of KS C 0304 1998 by using a measurement device of a network analyzer (E5071C) manufacturer of Agilent, a test effect test jig (EM-2107A) manufacturer of Electro-Metrics, and the like.

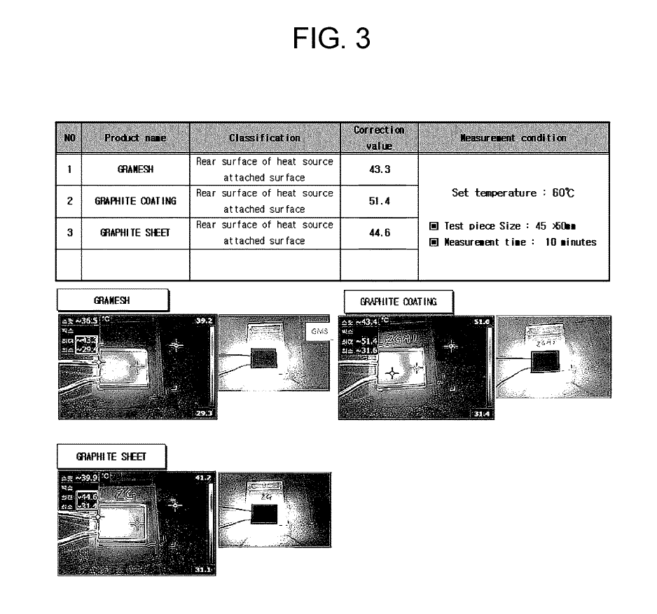

The shield sheet used in an electronic device according to the related art has an average shield rate of 55 to 65 dB, but the multi-functional sheet of the present invention is an excellent shield sheet that shows a shield rate of 71.854 to 84.491 dB as illustrated in FIG. 2.

The dissipation of heat was measured by an E63900 device of an infrared thermal image camera manufacturer of FLIR of Sweden (a measurement condition: a temperature was measured after 10 minutes elapsed from a set temperature of 60 degrees), and the multi-functional sheet according to the present invention is a heat dissipating sheet having an excellent heat dissipating effect as compared with the graphite sheet and graphite coating according to the related art.

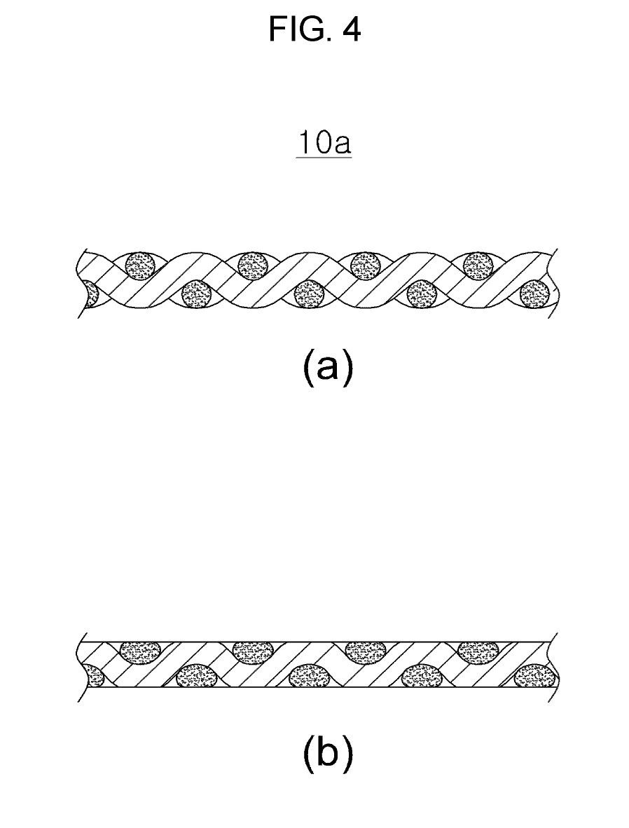

Although the graphite sheet according to the related art showed a measured temperature of 44.6 degrees and the graphite coating sheet showed 51.4 degrees, the multi-functional sheet (NO 1) of the present invention showed an excellent heat dissipating effect corresponding to 43.3 degrees as illustrated in FIG. 3.

Structure 2

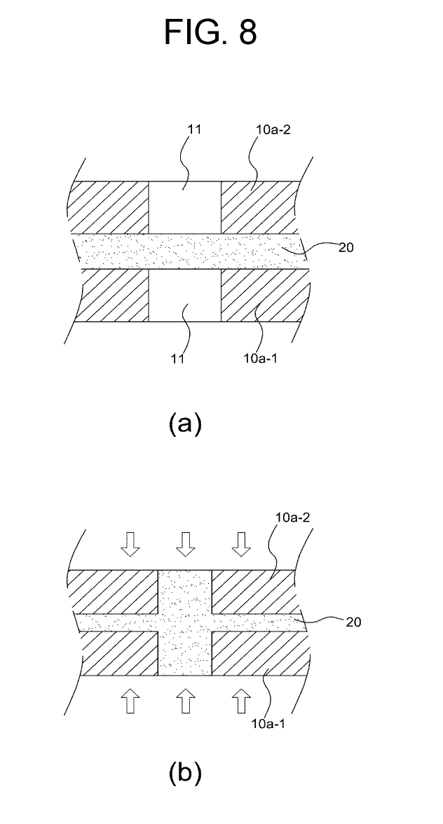

First, the graphite sheet may be classified into a first graphite sheet 20-1 formed on one surface of the metal sheet 10a, and a second graphite sheet 20-2 formed on an opposite surface of the metal sheet 10a. That is, as illustrated in FIG. 7, the multi-functional sheet of structure 2 has the graphite sheets 20-1 and 20-2 on opposite surfaces of the metal sheet 10a, and the method for coupling the metal sheet and the graphite sheet is the same as those of structure 1. The first graphite sheet 20-1 and the second graphite sheet 20-2 formed on the opposite surfaces of the metal sheet 10a penetrate into the pores 11 formed in the metal sheet 10a through pressing to contact each other, and the thickness of the multi-functional sheet is 90 to 140 μm.

Structure 3

First, the metal sheet may be classified into a first metal sheet 10a-1 formed on one surface of the graphite sheet 20, and a second metal sheet 10a-2 formed on an opposite surface of the graphite sheet 20. That is, in the multi-functional sheet of structure 3, the graphite sheet 20 is situated between the two metal sheets 10a-1 and 10a-2, and the method for coupling the metal sheets and the graphite sheet is the same as that of structure 1. The graphite sheet 20 formed between the first metal sheet 10a-1 and the second metal sheet 10a-2 penetrates into the pores 11 formed in the first metal sheet 10a-1 and the pores 11 formed in the second metal sheet 10a-2 through pressing, and the thickness of the pressed multi-functional sheet becomes 90 to 160 μm.

### Second Embodiment

A multi-functional sheet for shielding electromagnetic waves and dissipating heat at a high performance according to a second embodiment of the present invention includes a metal layer 10, a graphite sheet 20, and a protective layer 50.

The graphite sheet 20 has an excellent heat dissipating performance, and a metal layer 10 is formed on one surface or opposite surfaces of the graphite sheet 20 through sputtering deposition. The metal layer 10 may be formed of copper, aluminum, silver, or the like.

The sputtering is performed in a vacuum state, and an electric field is applied to a target material which is to be deposited and a part (copper (Cu) is formed on a surface of the graphite sheet 20, which is to be coated, in the present embodiment) and plasma is generated between the target material (Cu) and the graphite sheet 20 to collide with the metal (Cu) that is the target material while Ar+ that is an inert gas moves towards the target material (Cu) connected to a negative electrode, so that metal (Cu) particles are popped out and are stacked on an opposite surface of the graphite sheet 20.

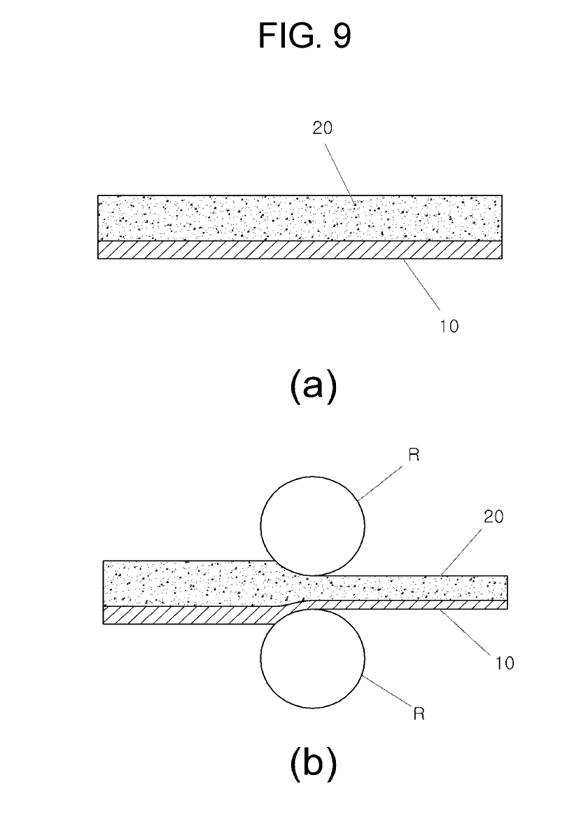

As illustrated in FIG. 9, the metal layer 10 formed on one surface of the graphite sheet 20 by the sputtering deposition has a thickness of 300 to 1000 Å. Further, the graphite sheet 20 in which the metal sheet 10 is formed may be manufactured to have a very thin thickness of not more than 40 μm through rolling of rollers R.

In this way, because the graphite sheet 20 in which the metal layer 10 is formed is pressed through rolling of the rollers R, a flattening degree of the graphite sheet 20 in which the metal layer 10 is formed may be increased and the tissues of the graphite sheet 20 become dense so that heat dissipating performance may be improved.

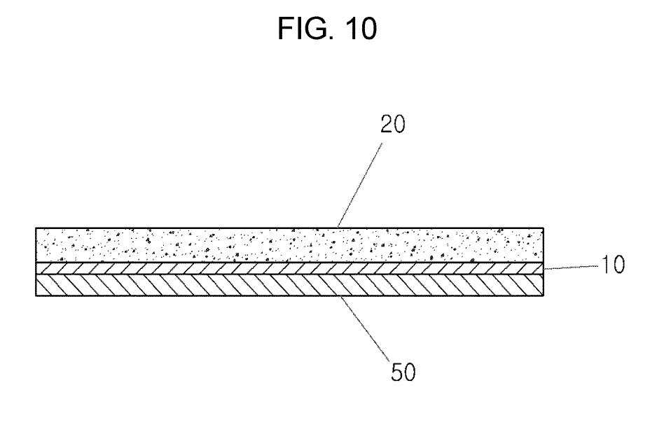

Further, in order to prevent oxidation of the metal after the metal layer 10 is formed on a surface of the graphite sheet 20, as illustrated in FIG. 10, the protective layer 50 is formed on a surface of the graphite sheet 20 in which the metal layer 10 is formed. That is, the protective layer 50 covers the metal layer 10 formed on a surface of the graphite sheet 20.

Further, a release paper 40 in which an adhesive layer 30 having conductive and insulating characteristics is formed may be attached to one surface or opposite surfaces of the graphite sheet 20 according to the characteristics of the product to which the present invention is applied.

As described above, the multi-functional sheet for shielding electromagnetic waves and dissipating heat at a high performance according to the present invention may further improve a heat dissipating effect because a thermal resistance by a resin is not generated by forming the metal layer 10 on a surface of the graphite sheet 20 without using a separate resin adhesive.

The shield rate of the multi-functional sheet for shielding electromagnetic waves and dissipating heat at a high performance according to the second embodiment of the present invention is measured in a frequency area of 30 MHz to 1.5 GHz by the measurement standard of KS C 0304 1998 by using a measurement device of a network analyzer (E5071C) manufacturer of Agilent, a test effect test jig (EM-2107A) manufacturer of Electro-Metrics, and the like.

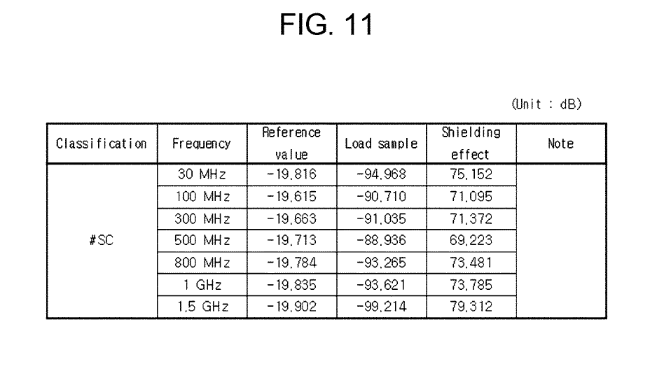

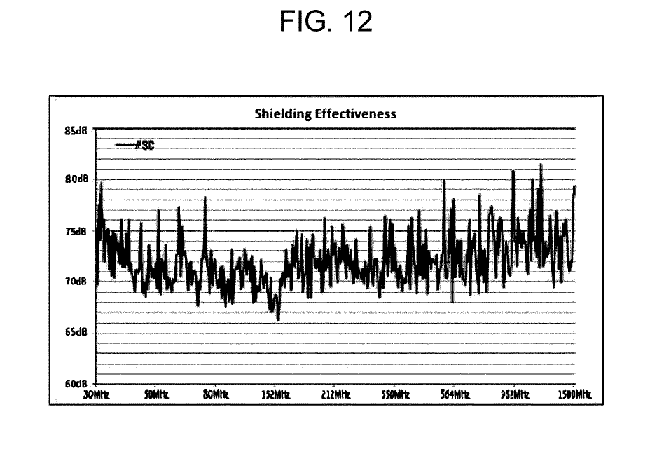

A general shielding sheet used for an electronic device according to the related art showed an average shielding rate of 55 to 56 dB, but the multi-functional sheet for shielding electromagnetic waves and dissipating heat at a high performance according to the embodiment of the present invention showed a high shielding rate of 69.2 to 79.3 dB (see FIGS. 11 and 12).

The dissipation of heat by the multi-functional sheet for shielding electromagnetic waves and dissipating heat at a high performance according to the embodiment of the present invention was measured by an E63900 device of an infrared thermal image camera manufacturer of FLIR of Sweden (a measurement condition: a temperature was measured after 10 minutes elapsed from a set temperature of 60 degrees), and it can be seen that the multi-functional sheet according to the present invention is a heat dissipating sheet having an excellent heat dissipating effect as compared with the graphite sheet or graphite coating according to the related art

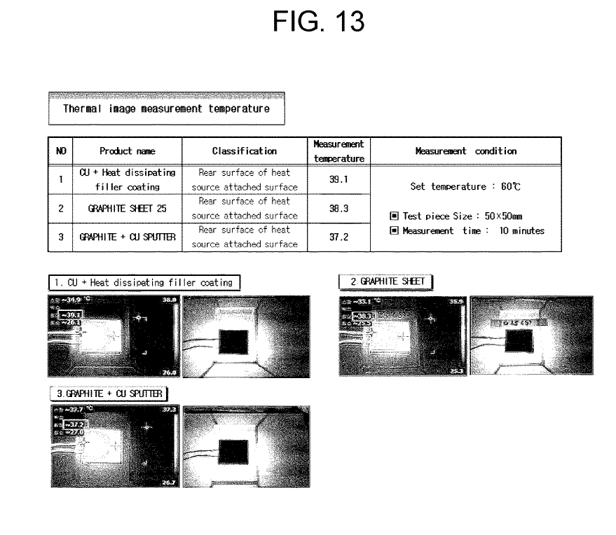

The measured temperature of the graphite sheet according to the related art is 38.4 degrees and the measured temperature of the heat dissipating filler coating sheet is 39.1 degrees, but the multi-functional sheet (NO 3) according to the second embodiment of the present invention showed an excellent heat dissipating effect corresponding to a measured temperature of 37.2 degrees (see FIG. 13).

Meanwhile, in the multi-functional sheet for shielding electromagnetic waves and dissipating heat at a high performance according to the present invention, a solid state metal or nonmetal may be converted into a gas and may be attached to a surface of the graphite sheet 20 by applying high energy of vacuum coating in a vacuum condition of 10 to 15 Torr.

The multi-functional sheet for shielding electromagnetic waves and dissipating heat at a high performance according to the present invention is not limited to the above-mentioned embodiments, and may be variously deformed without departing from the spirit of the present invention.

The multi-functional sheet for shielding electromagnetic waves and dissipating heat at a high performance according to the present invention may be attached to the interior of a mobile device or the inside of an LCD window glass of an electronic device to interrupt electromagnetic waves generated by the mobile device or the electronic device and improve heat dissipating characteristics of the mobile device or electronic device.

What is claimed is:

1. A multi-functional sheet for shielding electromagnetic waves and dissipating heat at a high performance which is manufactured by pressing a metal layer to a graphite sheet, wherein the metal layer is a metal sheet having a plurality of pores, the graphite sheet penetrates into the pores through pressing of rollers, a thickness of the metal sheet is made to be smaller through pressing of the rollers and sizes of the pores becomes smaller such that the metal sheet is coupled to the graphite sheet, and a depth by which the graphite penetrates into the pores through the pressing of the rollers is larger than 15% of the thickness of the metal sheet.

2. The multi-functional sheet of claim 1, further comprising:
a release paper that is bonded to one surface of the metal sheet,
wherein the graphite sheet is formed on an opposite surface of the metal sheet, and the release paper, the metal sheet, and the graphite sheet that are sequentially stacked are pressed by rollers.

3. The multi-functional sheet of claim 1, wherein the graphite sheet comprises a first graphite sheet formed on one surface of the metal sheet and a second graphite sheet formed on an opposite surface of the metal sheet, and the first graphite sheet and the second graphite sheet penetrate into the pores to contact each other through pressing.

4. The multi-functional sheet of claim 1, wherein the metal sheet comprises a first metal sheet formed on one surface of the graphite sheet and a second metal sheet formed on an opposite surface of the graphite sheet, and the graphite sheet penetrates into pores formed in the first metal sheet and pores formed in the second metal sheet.

5. A multi-functional sheet for shielding electromagnetic waves and dissipating heat at a high performance which is manufactured by pressing a metal layer to a graphite sheet, wherein the metal layer is formed on one surface or opposite surfaces of the graphite sheet through sputtering deposition and the stack structure of the metal layer and the graphite sheet is pressed to have a thickness of not more than 40 μm.
